(19) United States
(12) Patent Application Publication
(10) Pub. No.: US 2017/0339788 A1
(43) Pub. Date: Nov. 23, 2017

(54) SPLIT VIA SECOND DRILL PROCESS AND STRUCTURE

(71) Applicant: Multek Technologies Limited, San Jose, CA (US)

(72) Inventors: Znewa Zeng, Guangdong (CN); Pui Yin Yu, Tsuen Wan (HK)

(73) Assignee: Multek Technologies Limited, San Jose, CA (US)

(21) Appl. No.: 15/176,063

(22) Filed: Jun. 7, 2016

(30) Foreign Application Priority Data
May 18, 2016 (CN) 201610330939.3

(51) Int. Cl. H05K 1/11; H05K 3/40; H05K 3/06; H05K 3/46; H05K 1/02

(52) U.S. Cl. CPC H05K 1/115; H05K 3/4652; H05K 1/0298; H05K 3/06; H05K 3/4038

(57) ABSTRACT

A printed circuit board has multiple stacked layers laminated together. A through hole is formed through the laminated stack, and plating is applied to the side walls of the though hole, thereby forming a plated through hole. Second through holes are then formed through the laminated stack, where each second through hole overlaps an edge of the plated through hole. By aligning the second through holes at the edge of the plated through hole, the plating of the plated through hole coincident with each second through hole is removed, thereby separating the plated through hole into two separate circuit paths. Forming second through holes in this manner effectively splits the circuit path of the plated through hole into multiple separate circuit paths, which increases the circuit density of the printed circuit board.

### CROSS-REFERENCE TO RELATED APPLICATION(S)

This application claims priority under 35 U.S.C. §119(a)-(d) of the Chinese Patent Application No: 201610330939.3, filed May 18, 2016 and titled, “SPLIT VIA BY SECOND DRILL PROCESS AND STRUCTURE,” which is hereby incorporated by reference in its entirety for all purposes.

### FIELD OF THE INVENTION

The present invention is generally directed to printed circuit boards. More specifically, the present invention is directed to printed circuit boards having plated through holes that are each split into multiple separate circuit paths.

### BACKGROUND OF THE INVENTION

A printed circuit board (PCB) mechanically supports and electrically connects electronic components using conductive traces, pads and other features etched from electrically conductive sheets, such as copper sheets, laminated onto a non conductive substrate. Multi-layered printed circuit boards are formed by stacking and laminating multiple such etched conductive sheet/non-conductive substrate. Conductors on different layers are interconnected with plated through holes called vias.

A printed circuit board includes a plurality of stacked layers, the layers made of alternating non-conductive layers and conductive layers. The non-conductive layers can be made of prepreg or base material that is part of a core structure, or simply core. Prepreg is a fibrous reinforcement material impregnated or coated with a resin binder, and consolidated and cured to an intermediate stage semi solid product. Prepreg is used as an adhesive layer to bond discrete layers of multilayer PCB construction, where a multilayer PCB consists of alternative layers of conductors and base materials bonded together, including at least one internal conductive layer. A base material is an organic or inorganic material used to support a pattern of conductor material. A core is a metal clad base material where the base material has integral metal conductor material on one or both sides. A laminated stack is formed by stacking multiple core structures with intervening prepreg and then laminating the stack. A via is then formed by drilling a hole through the laminated stack and plating the wall of the hole with electrically conductive material, such as copper. The resulting plating interconnects the conductive layers in the laminated stack. In this manner, each plated through hole forms a single circuit path to which one, some or all of the conductive layers in the laminated stack can be electrically connected. A single conductive trace on the top and/or bottom surface of the laminated stack is connected to the plated through hole. A circuit density of the PCB is determined in part by the number of plated through holes that are able to be fabricated in the laminated stack.

### SUMMARY OF THE INVENTION

Embodiments are directed to a printed circuit board having multiple stacked layers laminated together. A through hole is formed through the laminated stack, and plating applied to the side walls of the though hole, thereby forming a plated through hole. The plated through hole can either be filled with a non-conductive material, such as epoxy, or left unfilled. Second through holes are then formed through the laminated stack, where each second through hole overlaps an edge of the plated through hole. Preferably, each second through hole is centered at the edge of the plated through hole. In some embodiments, two second through holes are formed. In other embodiments, more than two second through holes are formed. By aligning the second through holes over the edge of the plated through hole, the plating of the plated through hole coincident with each second through hole is removed, thereby separating the plated through hole into two separate circuit paths, in the case of two second through holes. Separate conductive traces, or lead lines, are connected to each separate circuit path of the plated through hole by selectively etching a conductive layer on the top and/or bottom surface of the laminated stack. Forming second through holes in this manner effectively splits the circuit path of the plated through hole into multiple separate circuit paths, which increases the circuit density of the printed circuit board.

In an aspect, a printed circuit board is disclosed. The printed circuit board includes a laminated stack, a plated through hole through the laminated stack, a plurality of second through holes each aligned to overlap an edge of the plated through hole, and a plurality of conductive traces. The laminated stack includes a plurality of non-conductive layers and a plurality of conductive layers. Each second through hole is aligned to overlap the edge of the plated through hole such that plating of the plated through hole coincident with each of the second through holes is removed. The remaining plating in the plating through hole forms a plurality of separate circuit paths. The plurality of conductive interconnects are formed on an outer surface of the laminated stack. Each of the conductive interconnects is coupled to a corresponding one of the plurality of separate circuit paths. In some embodiments, each of the plurality of separate circuit paths is coupled to one of more of the plurality of conductive layers in the laminated stack. In some embodiments, the plated through hole is filled with a non-conductive material. In some embodiments, the non-conductive material is epoxy. In some embodiments, each of the conductive layers is pattern etched. In some embodiments, each of the separate circuit paths are electrically isolated from each other.

In another aspect, a method of manufacturing a printed circuit board is disclosed. The method includes forming a laminated stack of a plurality of non-conductive layers and a plurality of conductive layers. The method also includes forming a through hole through the laminated stack. The method also includes plating side walls of the through hole to form a plated through hole. The method also includes forming a plurality of second through holes through the laminated stack. Each second through hole is aligned to overlap an edge of the plated through hole such that plating of the plated through hole coincident with each of the second through holes is removed. Remaining plating in the plating through hole forms a plurality of separate circuit paths. The method also includes pattern etching an outer conductive layer of the laminated stack to form a plurality of conductive interconnects. Each of the conductive interconnects is coupled to a corresponding one of the plurality of separate circuit paths. In some embodiments, the method also includes pattern etching the conductive layers in the laminated stack prior to forming the printed circuit board stack up. In some embodiments, each of the plurality of separate circuit paths is coupled to one of more of the plurality of conductive layers in the laminated stack. In some embodiments, the method also includes filling the plated through hole with a non-conductive material prior to forming the plurality of second through holes. In some embodiments, the non-conductive material is epoxy. In some embodiments, each of the separate circuit paths are electrically isolated from each other. In some embodiments, pattern etching the outer conductive layer comprises applying a dry film to the outer conductive layer, pattern etching the dry film to selectively expose portions of the outer conductive layer, plating tin at the exposed portions of the outer conductive layer, stripping the dry film, etching the outer conductive layer at portions corresponding to the stripped dry film, and stripping the tin.

### BRIEF DESCRIPTION OF THE DRAWINGS

Several example embodiments are described with reference to the drawings, wherein like components are provided with like reference numerals. The example embodiments are intended to illustrate, but not to limit, the invention. The drawings include the following figures:

FIGS. 1-7B illustrate various steps in the process used to manufacture a printed circuit board according to some embodiments.

### DETAILED DESCRIPTION OF THE EMBODIMENTS

Embodiments of the present application are directed to a printed circuit board. Those of ordinary skill in the art will realize that the following detailed description of the printed circuit board is illustrative only and is not intended to be in any way limiting. Other embodiments of the printed circuit board will readily suggest themselves to such skilled persons having the benefit of this disclosure.

Reference will now be made in detail to implementations of the printed circuit board as illustrated in the accompanying drawings. The same reference indicators will be used throughout the drawings and the following detailed description to refer to the same or like parts. In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

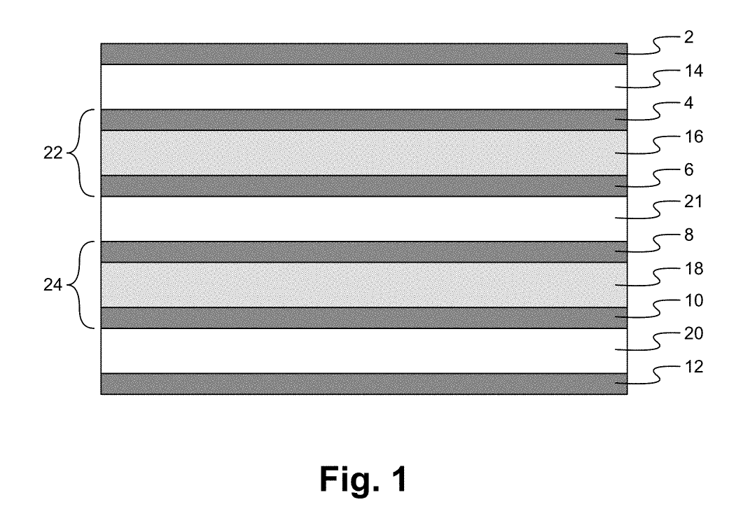

FIGS. 1-7B illustrate various steps in the process used to manufacture a printed circuit board according to some embodiments. FIG. 1 illustrates a cut out side view of a laminated stack that forms a basis for a printed circuit board according to some embodiments. The laminated stack has a plurality of non-conductive layers and a plurality of conductive layers. In the exemplary configuration shown in FIG. 1, the printed circuit board includes conductive layers 2, 4, 6, 8, 10 and 12 and non-conductive layers 14, 16, 18, 20 and 21. Prior to lamination, each inner conductive layer, for example conductive layers 4, 6, 8 and 10, is pattern etched to form electrically conductive interconnects. Although not shown in FIG. 1, electrically conductive vias can be formed in the laminated stack to electrically interconnect one or more conductive layers. A conductive layer can be formed, for example, from a copper foil or laminate, where a laminate includes a non-conductive layer such as base material and a conductive layer on one or both sides of non-conductive layer. In some embodiments, a conductive layer is representative of a multilayer buildup that can include many interspersed conductive and non-conductive layers.

Each non-conductive layer is made of a non-conductive, insulating layer, such as prepreg or base material. A base material is an organic or inorganic material used to support a pattern of conductor material. Base material and prepreg each include resin and glass cloth, but the resin in base material is already fully cured and as such does not flow during lamination. The resin in prepreg is only partially cured and therefore flows during lamination. A function of prepreg is to bind inner cores together during lamination.

In some embodiments, the laminated stack is formed by first fabricating one or more inner core structures. In the exemplary configuration shown in FIG. 1, there are two inner core structures 22 and 24. It is understood that a laminated stack can be fabricated with more or less than two inner core structures. Each core structure is a metal clad structure including a non-conductive layer and a conductive layer formed on one or both opposing surfaces of the non-conductive layer. It is understood that an alternative inner core structure can be used which includes a conductive layer on only one surface of the non-conductive layer. The exemplary inner core structure 22 includes the non-conductive layer 16 and the conductive layers 4 and 6. The conductive layers 4 and 6 are selectively pattern etched. The exemplary inner core structure 24 includes the non-conductive layer 18 and the conductive layers 8 and 10. The conductive layers 8 and 10 are selectively pattern etched. The inner core structures 22 and 24 are stacked with intervening non-conductive layer 21, such as prepreg. Outer conductive layers 2 and 12 and intervening non-conductive layers 14 and 20, such as prepreg layers, are added to the stack. In some embodiments, the outer conductive layers 2 and 12 and not pattern etched and are left as a sheet. The stack up is then laminated to form the laminated stack shown in FIG. 1. It is understood that more or less than the number of layers shown in FIG. 1 can be used to form a printed circuit board laminated stack.

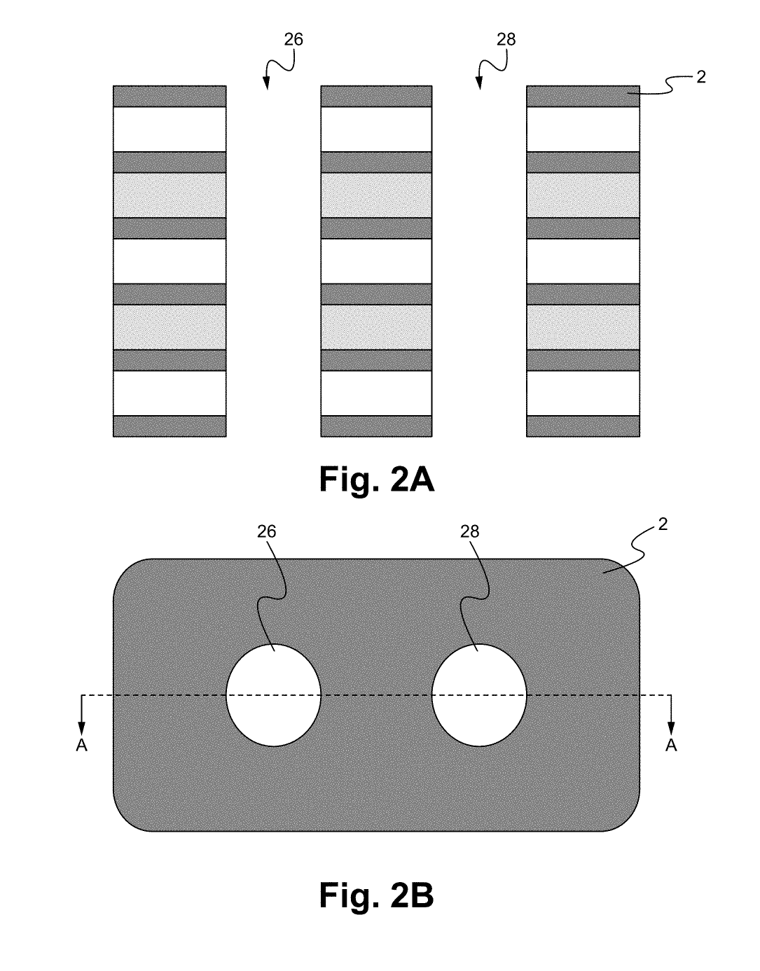

In FIGS. 2A and 2B, selective holes are formed through the laminated stack of FIG. 1 to form one or more through holes. FIG. 2B shows a top down view of the laminated stack, and FIG. 2A shows a cut out side view of the laminated stack along section A-A shown in FIG. 2B In some embodiments, the through holes are formed using a routing process including, but not limited to, mechanical routing (drilling), laser routing or mechanical plus laser routing. The exemplary configuration shown in FIG. 2A shows two through holes 26 and 28 formed in the laminated stack. It is understood that more or less than two through holes can be formed.

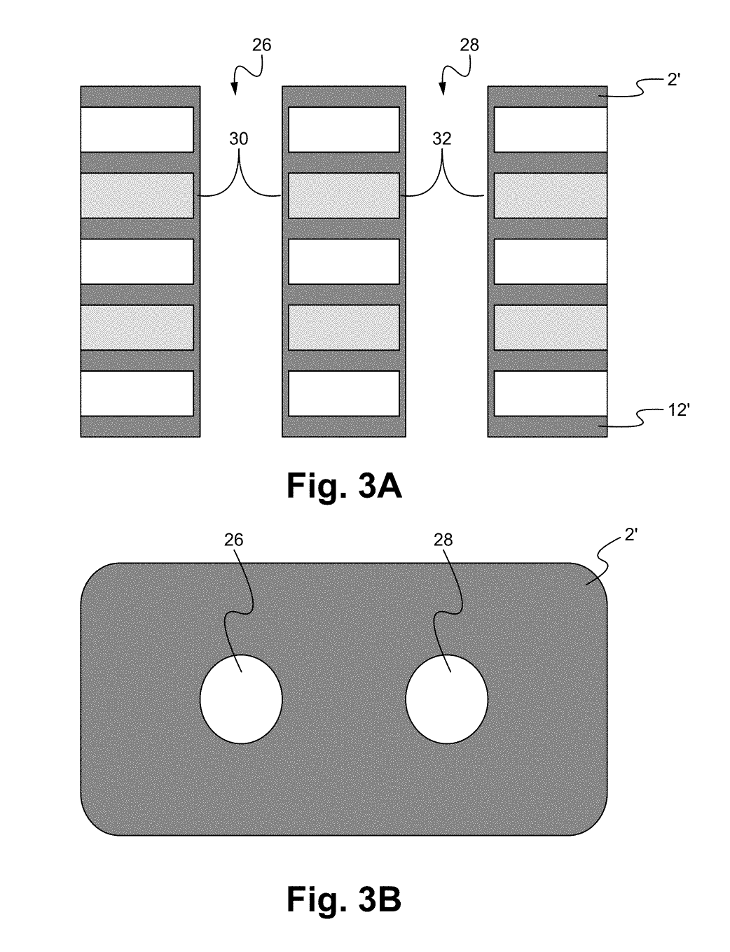

In FIGS. 3A and 3B, a desmear process is performed to remove residue, such as residual particles from the drilling of through holes 26 and 28. Next, a plating process is performed, such as electroless plating. The plating process forms plating 30 on the side walls of the through hole 26 and plating 32 on the side walls of the through hole 28. The plating is formed an all portions of the through hole side walls and as such the plating for a given through hole forms a single circuit path. The plating process also results in plating material on the outer conductive layers 2′ and 12′. In some embodiments, copper is used as the plating material. It is understood that other plating materials can be used. The plating 30 and the plating 32 form interconnects with various conductive layers in the laminated stack.

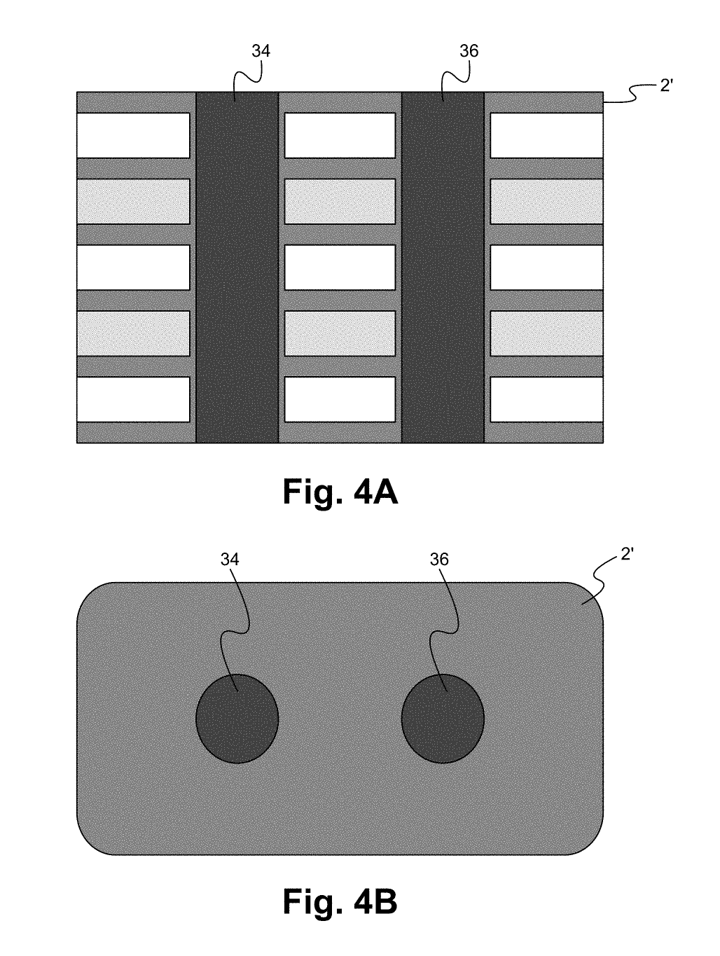

In FIGS. 4A and 4B, an optional step is performed of plugging the through holes 26 and 28 with non-conductive material, such as epoxy.

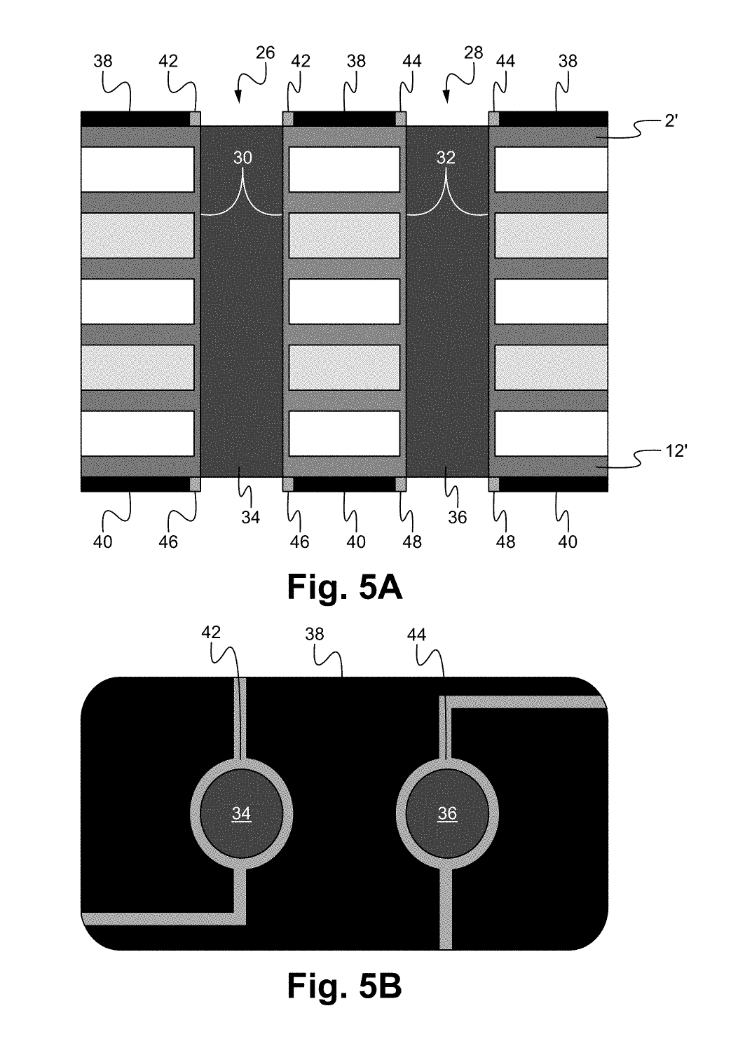

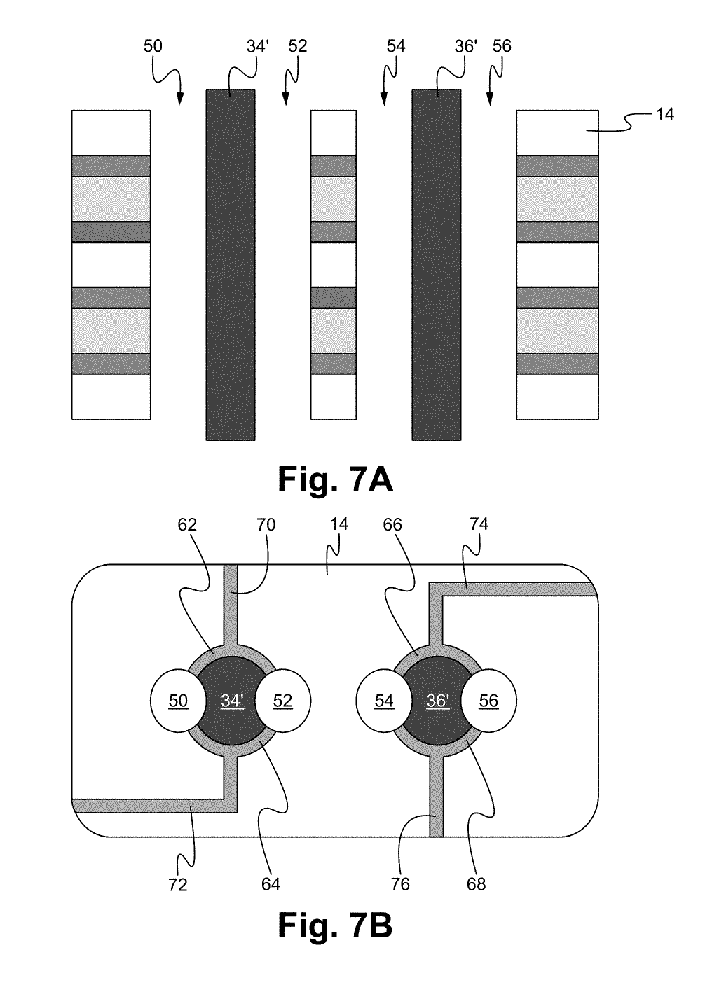

In FIGS. 5A and 5B, dry film and pattern tin plating steps are performed. Dry film 38 is selectively applied to the outer conductive layer 2′ and dry film 40 is selectively applied to the outer conductive layer 12′. Tin is deposited to form patterned tin plating 42 and patterned tin plating 44 on the outer conductive layer 2′, and to form patterned tin plating 46 and patterned tin plating 48 on the outer conductive layer 12′. The patterned tin plating forms a mask for a subsequent etching step performed on the outer conductive layers 2′ and 12′, described below in relation to FIGS. 7A and 7B. In some embodiment, the patterned tin plating is formed around the edges of each through hole, as well as forming lead lines extending away from each through hole.

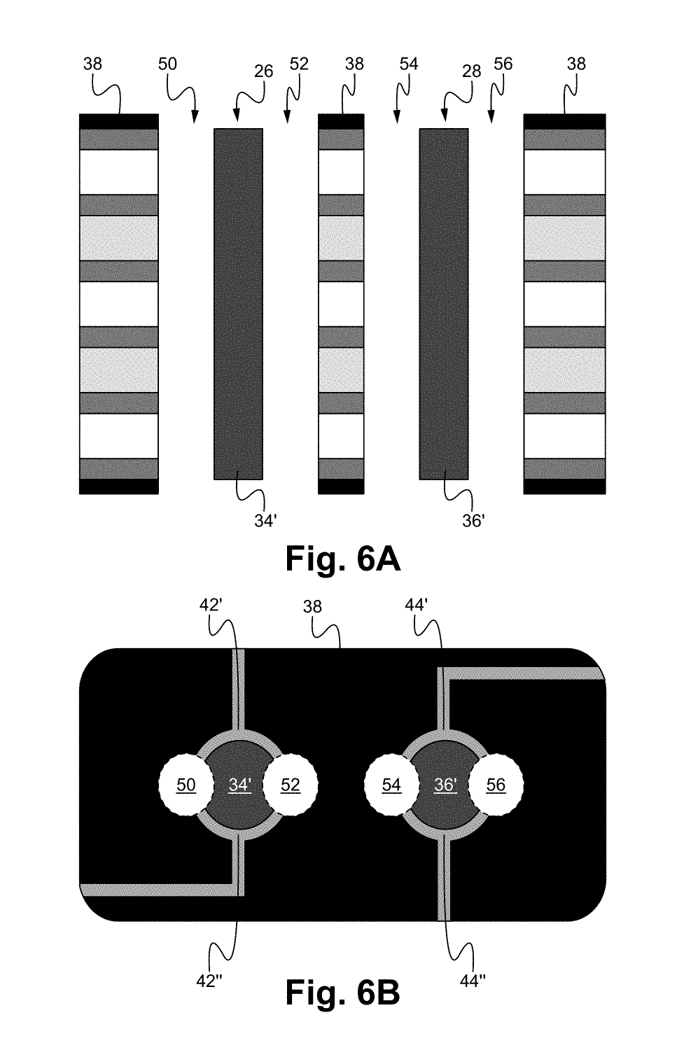

In FIGS. 6A and 6B, multiple second through holes are formed over an edge of each through hole such that each through hole is split into multiple circuit paths. Specifically, second through holes 50 and 52 are formed through the laminated stack, where each second through hole 50 and 52 overlaps an edge of the plated through hole 26. By aligning the second through holes 50 and 52 over the edge of the plated through hole 26, the plating 30 (FIG. 5A) of the plated through hole 26 coincident with each second through hole 50 and 52 is removed, thereby separating the plated through hole into two separate circuit paths. Forming second through holes 50 and 52 in this manner effectively splits the circuit path of the plated through hole 26 into two separate circuit paths, which increases the circuit density of the printed circuit board. Similarly, second through holes 54 and 56 are formed through the laminated stack, where each second through hole 54 and 56 overlaps an edge of the plated through hole 28, thereby splitting the circuit path of the plated through hole 28 into two separate circuit paths. As shown in FIG. 6B, the tin plating 42 (FIG. 5B) is split into tin plating 42′ and 42″, each indicative of a separate circuit path underneath. Each separate circuit path is connected to a separate lead line.

FIGS. 6A and 6B show two second through holes formed for each plated through hole. It is understood that more than two second through holes can be formed for each plated through hole, with each additional second through hole forming an additional separate circuit path.

In an optional step, the second through holes 50, 52, 54, 56 can be plugged with a non-conductive material, such as epoxy.

In FIGS. 7A and 7B, conductive layers 2′ and 12′ are selectively pattern etched to form separate circuit paths. Specifically, the dry film 38 is stripped, thereby exposing corresponding underlying conductive layer 2′. The remaining patterned tin plating 42′, 42″ (FIG. 6B) functions as a mask for pattern etching the exposed portions of the conductive layer 2′. In some embodiments, the exposed portions of the conductive layer 2′ are alkaline etched. After pattern etching the conductive layer 2′, the tin plating 42′, 44′ is stripped, leaving the portion of the conductive layers 2′ underlying the tin plating. The remaining pattern etched portions of the conductive layers 2′ form separate circuit paths 62 and 64 in the plated through hole 26 and separate circuit paths 66 and 68 in the plated through hole 28. Each separate circuit path 62, 64, 66, 68 has a separate conductive lead line 70, 72, 74, 76, respectively. The dry film 40, the conductive layer 12′ and the tin plating 46, 48 are similarly processed as the dry film 38, the conductive layer 2′ and the tin plating 42, 44.

It is understood that the various structural configurations, as well as the positions and numbers of the through holes and second through holes shown in the embodiments of FIGS. 1-7B can be interchanged according to a specific application and application requirement.

The present application has been described in terms of specific embodiments incorporating details to facilitate the understanding of the principles of construction and operation of the printed circuit board. Many of the components shown and described in the various figures can be interchanged to achieve the results necessary, and this description should be read to encompass such interchange as well. As such, references herein to specific embodiments and details thereof are not intended to limit the scope of the claims appended hereto. It will be apparent to those skilled in the art that modifications can be made to the embodiments chosen for illustration without departing from the spirit and scope of the application.

1. A printed circuit board comprising:
a. a laminated stack of a plurality of non-conductive layers and a plurality of conductive layers;
b. a plated through hole formed through the laminated stack;
c. a plurality of second through holes, each second through hole aligned to overlap an edge of the plated through hole such that plating of the plated through hole coincident with each of the second through holes is removed, wherein remaining plating in the plating through hole forms a plurality of separate circuit paths; and
d. a plurality of conductive interconnects formed on an outer surface of the laminated stack, wherein each of the conductive interconnects is coupled to a corresponding one of the plurality of separate circuit paths.

2. The printed circuit board of claim 1 wherein each of the plurality of separate circuit paths is coupled to one of more of the plurality of conductive layers in the laminated stack.

3. The printed circuit board of claim 1 wherein the plated through hole is filled with a non-conductive material.

4. The printed circuit board of claim 3 wherein the non-conductive material is epoxy.

5. The printed circuit board of claim 1 wherein each of the conductive layers is formed as a patterned interconnect.

6. The printed circuit board of claim 1 wherein each of the separate circuit paths are electrically isolated from each other.

7. A method of manufacturing a printed circuit board comprising:
a. forming a laminated stack of a plurality of non-conductive layers and a plurality of conductive layers;
b. forming a through hole through the laminated stack;
c. plating side walls of the through hole to form a plated through hole;
d. forming a plurality of second through holes through the laminated stack, each second through hole is aligned to overlap an edge of the plated through hole such that plating of the plated through hole coincident with each of the second through holes is removed, wherein remaining plating in the plating through hole forms a plurality of separate circuit paths; and
e. pattern etching an outer conductive layer of the laminated stack to form a plurality of conductive interconnects, wherein each of the conductive interconnects is coupled to a corresponding one of the plurality of separate circuit paths.

8. The method of claim 7 further comprising pattern etching the conductive layers in the laminated stack prior to forming the printed circuit board stack up.

9. The method of claim 7 wherein each of the plurality of separate circuit paths is coupled to one of more of the plurality of conductive layers in the laminated stack.

10. The method of claim 7 further comprising filling the plated through hole with a non-conductive material prior to forming the plurality of second through holes.

11. The method of claim 10 wherein the non-conductive material is epoxy.

12. The method of claim 7 wherein each of the separate circuit paths are electrically isolated from each other.

13. The method of claim 7 wherein pattern etching the outer conductive layer comprises:
a. applying a dry film to the outer conductive layer;
b. pattern etching the dry film to selectively expose portions of the outer conductive layer;
c. plating tin at the exposed portions of the outer conductive layer;
d. stripping the dry film;
e. etching the outer conductive layer at portions corresponding to the stripped dry film; and
f. stripping the tin.

14. The printed circuit board of claim 1 wherein the plurality of second through holes are filled with a non-conductive material.

15. The printed circuit board of claim 1 wherein the outer surface of the laminated stack comprises a first outer surface, and the laminated stack further comprises a second outer surface on an opposing side of the laminated stack as the first outer surface, wherein the plurality of conductive interconnects are a plurality of first conductive interconnects formed on the first outer surface, each of the first conductive interconnects is coupled to the corresponding one of the plurality of separate circuit paths on the first outer surface, further wherein the printed circuit board further comprises a plurality of second conductive interconnects, each second conductive interconnect is coupled to a corresponding one of the plurality of separate circuit paths on the second outer surface.

16. The printed circuit board of claim 1 wherein each of the conductive interconnects is coupled to the corresponding one of the plurality of separate circuit paths such that the conductive interconnect and an end portion of the corresponding one of the plurality of separate circuit paths are co-planar.
